(19) United States
(12) Patent Application Publication
(10) Pub. No.: US 2016/0093649 A1
(43) Pub. Date: Mar. 31, 2016

(54) SEMICONDUCTOR DEVICE AND RELATED MANUFACTURING METHOD

(71) Applicant: Semiconductor Manufacturing International (Shanghai) Corporation, Shanghai (CN)

(72) Inventors: Xuemei WANG, Shanghai (CN); Fugang CHEN, Shanghai (CN); Shuaibing LIN, Shanghai (CN); Feng HUANG, Shanghai (CN)

(21) Appl. No.: 14/863,861

(22) Filed: Sep. 24, 2015

(30) Foreign Application Priority Data
Sep. 25, 2014 (CN) 201410495194.7

(51) Int. Cl. H01L 27/146; H01L 21/266; H01L 21/265

(52) U.S. Cl. CPC H01L 27/1461; H01L 21/26513; H01L 21/266; H01L 27/14612; H01L 27/14643; H01L 27/14689; H01L 27/1463

(57) ABSTRACT

A method for manufacturing a semiconductor device may include the following steps: preparing a substrate; providing a gate material layer that overlaps the substrate; providing a blocking layer that partially covers the gate material layer; removing a portion of the gate material layer that is not covered by the blocking layer for forming a gate electrode; providing a blocking material layer that covers both the blocking layer and the substrate; removing a portion of the blocking material layer for forming a blocking member that has an opening, wherein the opening partially exposes the blocking layer and partially exposes the substrate; and performing ion implantation through the opening to form a doped well region in the substrate.

### CROSS-REFERENCE TO RELATED APPLICATION

This application claims priority to and benefit of Chinese Patent Application No. 201410495194.7, filed on 25 Sep. 2014, the Chinese Patent Application being incorporated herein by reference in its entirety.

### BACKGROUND OF THE INVENTION

The present invention is related to a semiconductor device and a method for manufacturing the semiconductor device. For example, the semiconductor device may be related to an image sensor device.

A semiconductor device, such as a complementary metal-oxide-semiconductor (CMOS) image sensor device, may need to have sufficiently high sensitivity and sufficiently low power consumption, in order to satisfy particular application requirements. For attaining high sensitivity and low power consumption, dark current in the semiconductor device may need to be minimized.

### SUMMARY

An embodiment of the present invention may be related to a method for manufacturing a semiconductor device. The method may include the following steps: preparing a substrate (e.g., a semiconductor substrate); providing a gate material layer (e.g., a polycrystalline silicon layer) that may overlap the substrate; providing a blocking layer that may partially cover the gate material layer; removing a portion of the gate material layer that is not covered by the blocking layer for forming a gate electrode; providing a blocking material layer that may cover both the blocking layer and the substrate; removing a portion of the blocking material layer for forming a blocking member that has a hole, wherein the hole may partially expose the blocking layer and may partially expose the substrate; and performing ion implantation through the hole to form a doped well region (e.g., a photodiode well region) in the substrate.

An insulating material layer (e.g., an oxide layer) may be provided on the substrate before the gate material layer is provided. A portion of the insulating material layer that is not covered by the blocking layer may be removed for forming an insulating layer. The gate electrode and the insulating layer may form a gate structure.

The blocking layer may be formed of a first material. The blocking material layer and the blocking member may be formed of a second material different from the first material. An etch rate of the second material may be greater than an etch rate of the first material in a first etchant and/or in light of a first wavelength.

During the ion implantation, some ions may be provided through a portion of the hole that is positioned between the gate electrode and a portion of the blocking member.

During the ion implantation, some ions may be blocked by an exposed portion of the blocking layer that is exposed by the hole.

The method may include (sequentially or substantially simultaneously) removing the blocking member and the blocking layer after the doped well region has been formed.

A thickness of the blocking layer in a direction perpendicular to the substrate may be greater than or equal to 500 angstroms.

An edge of the gate electrode may be substantially aligned with an edge of the doped well region in a direction perpendicular to the substrate.

The method may include forming a dielectric region (e.g., a shallow trench isolation region) in the substrate. The blocking layer may be positioned between the gate electrode and a first portion of the blocking member in a direction perpendicular to the substrate before the ion implantation. A second portion of the blocking member may overlap the dielectric region in the direction perpendicular to the substrate before the ion implantation. The first portion of the blocking member may be positioned between the second portion of the blocking member and the hole in a direction parallel to the substrate before the ion implantation.

The hole, the gate electrode, the blocking layer, and the first portion of the blocking member may be positioned between the second portion of the blocking member and a third portion of the blocking member in the direction parallel to the substrate before the ion implantation.

The blocking layer may be positioned between the gate electrode and the first portion of the blocking member in a direction perpendicular to the substrate before the ion implantation. The first portion of the blocking member may be spaced from the third portion of the blocking member in a direction parallel to the substrate before the ion implantation. The gate electrode may be spaced from the third portion of the blocking member in the direction parallel to the substrate before the ion implantation. A distance between the gate electrode and the third portion of the blocking member may be less than a distance between the first portion of the blocking member and the third portion of the blocking member before the ion implantation.

An embodiment of the present invention may be related to semiconductor device. The semiconductor device may be related to, for example, an image sensor device. The semiconductor device may include the following elements: a substrate (e.g., a semiconductor substrate) that may include a doped well region; and a gate electrode that may overlap the substrate. An edge of the gate electrode may be substantially aligned with an edge of the doped well region in a direction perpendicular to a side (e.g., a bottom side) of the substrate.

Less than 5% of the doped well region may overlap the gate electrode in the direction perpendicular to the side of the substrate.

The semiconductor device may include the following elements: a blocking layer that may be positioned on the gate electrode; and a blocking member that partially covers the blocking layer and has a hole. The hole may partially expose the blocking layer and may expose the doped well region. The blocking layer and the blocking member may be removed for manufacturing, for example, an image sensor device.

An embodiment of the present invention may be related to a semiconductor device. The semiconductor device may be related to, for example, an image sensor device. The semiconductor device may include the following elements: a substrate (e.g., a semiconductor substrate) that may include a doped well region; a blocking member that may overlap the substrate and may have a hole, wherein the hole may expose the doped well region; a blocking layer that may be positioned between the substrate and a first portion of the blocking member in a direction perpendicular to (e.g., a bottom side of) the substrate and may be partially exposed by the hole; and a gate electrode that may be positioned between the substrate and the blocking layer.

The semiconductor device may include an insulating layer positioned between the substrate and the gate electrode. The gate electrode and the insulating layer may form a gate structure.

The blocking layer may be formed of a first material. The blocking member may be formed of a second material different from the first material. An etch rate of the second material may be greater than an etch rate of the first material in a first etchant and/or in light of a first wavelength.

A thickness of the blocking layer in the direction perpendicular to the substrate may be greater than or equal to 500 angstroms.

An edge of the gate electrode may be substantially aligned with an edge of the doped well region in the direction perpendicular to the substrate.

The substrate may include a dielectric region, e.g., a shallow trench isolation region. A second portion of the blocking member may overlap the dielectric region in the direction perpendicular to the substrate. The gate electrode, the blocking layer, and the hole may be positioned between the second portion of the blocking member and a third portion of the blocking member in a direction parallel to the substrate.

A distance between the gate electrode and the third portion of the blocking member in the direction parallel to the substrate may be less than a distance between the first portion of the blocking member and the third portion of the blocking member in the direction parallel to the substrate.

A distance between the blocking layer and the third portion of the blocking member in the direction parallel to the substrate may be less than a distance between the first portion of the blocking member and the third portion of the blocking member in the direction parallel to the substrate.

According to embodiments of the invention, in a process for manufacturing a semiconductor device, a doped well region may be formed in a substrate after a gate structure has been formed. Therefore, the doped well region may not be significantly affected by high-temperature processes performed for forming the gate structure. Advantageously, satisfactory quality of the doped well region may be retained, and the semiconductor device may have satisfactory quality.

According to embodiments of the invention, in a process for manufacturing a semiconductor device, an edge of a blocking layer may be substantially aligned with an edge of a gate structure, and the blocking layer may function as a mask during an ion implantation process performed for forming a doped well region in a substrate. Accordingly, an edge of the doped well region may be substantially aligned with the edge of the gate structure, and the doped well region may not significantly overlap the gate structure. Therefore, dark current in a semiconductor device may be minimized. Advantageously, satisfactory sensitivity and/or satisfactory efficiency of the semiconductor device may be attained.

The above summary may be related to some of many embodiments of the invention disclosed herein and may be not intended to limit the scope of the invention.

### BRIEF DESCRIPTION OF THE DRAWINGS

FIG. 1A, FIG. 1B, and FIG. 1C show schematic diagrams (e.g., schematic cross-sectional views) that illustrate elements and/or structures formed in a method for manufacturing a semiconductor device (e.g., a photodiode) in accordance with one or more embodiments of the present invention.

FIG. 2 shows a flowchart that illustrates steps in a method for manufacturing a semiconductor device (e.g., a photodiode) in accordance with one or more embodiments of the present invention.

FIG. 3A, FIG. 3B, FIG. 3C, FIG. 3D, FIG. 3E, FIG. 3F, and FIG. 3G show schematic diagrams (e.g., schematic cross-sectional views) that illustrate elements and/or structures formed in a method for manufacturing a semiconductor device in accordance with one or more embodiments of the present invention.

FIG. 4 shows a schematic diagram (e.g., a schematic cross-sectional view) that illustrates elements of a semiconductor device in accordance with one or more embodiments of the present invention.

### DETAILED DESCRIPTION

Example embodiments of the present invention are described with reference to the accompanying drawings. As those skilled in the art would realize, the described embodiments may be modified in various different ways, all without departing from the spirit or scope of the present invention. Embodiments of the present invention may be practiced without some or all of these specific details. Well known process steps and/or structures may not have been described in detail in order to not unnecessarily obscure the present invention.

The drawings and description are illustrative and not restrictive. Like reference numerals may designate like (e.g., analogous or identical) elements in the specification. Repetition of description may be avoided.

The relative sizes and thicknesses of elements shown in the drawings are for facilitate description and understanding, without limiting the present invention. In the drawings, the thicknesses of some layers, films, panels, regions, etc., may be exaggerated for clarity.

Illustrations of example embodiments in the figures may represent idealized illustrations. Variations from the shapes illustrated in the illustrations, as a result of, for example, manufacturing techniques and/or tolerances, may be possible. Thus, the example embodiments should not be construed as limited to the shapes or regions illustrated herein but are to include deviations in the shapes. For example, an etched region illustrated as a rectangle may have rounded or curved features. The shapes and regions illustrated in the figures are illustrative and should not limit the scope of the example embodiments.

Although the terms “first”, “second”, etc. may be used herein to describe various elements, these elements, should not be limited by these terms. These terms may be used to distinguish one element from another element. Thus, a first element discussed below may be termed a second element without departing from the teachings of the present invention. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

If a first element (such as a layer, film, region, or substrate) is referred to as being “on”, “neighboring”, “connected to”, or “coupled with” a second element, then the first element can be directly on, directly neighboring, directly connected to, or directly coupled with the second element, or an intervening element may also be present between the first element and the second element. If a first element is referred to as being “directly on”, “directly neighboring”, “directly connected to”, or “directed coupled with” a second element, then no intended intervening element (except environmental elements such as air) may also be present between the first element and the second element.

Spatially relative terms, such as “beneath”, “below”, “lower”, “above”, “upper”, and the like, may be used herein for ease of description to describe one element or feature's spatial relationship to another element(s) or feature(s) as illustrated in the figures. It will be understood that the spatially relative terms may encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein should be interpreted accordingly.

The terminology used herein is for the purpose of describing particular embodiments and is not intended to limit the invention. As used herein, the singular forms, “a”, “an”, and “the” may indicate plural forms as well, unless the context clearly indicates otherwise. The terms “includes” and/or “including”, when used in this specification, may specify the presence of stated features, integers, steps, operations, elements, and/or components, but may not preclude the presence or addition of one or more other features, integers, steps, operations, elements, components, and/or groups.

Unless otherwise defined, terms (including technical and scientific terms) used herein have the same meanings as commonly understood by one of ordinary skill in the art related to this invention. Terms, such as those defined in commonly used dictionaries, should be interpreted as having meanings that are consistent with their meanings in the context of the relevant art and should not be interpreted in an idealized or overly formal sense unless expressly so defined herein.

The term “connect” may mean “electrically connect”. The term “insulate” may mean “electrically insulate”. The term “conductive” may mean “electrically conductive”

Unless explicitly described to the contrary, the word “comprise” and variations such as “comprises”, “comprising”, “include”, or “including” may imply the inclusion of stated elements but not the exclusion of other elements.

Various embodiments, including methods and techniques, are described in this disclosure. Embodiments of the invention may also cover an article of manufacture that includes a non-transitory computer readable medium on which computer-readable instructions for carrying out embodiments of the inventive technique are stored. The computer readable medium may include, for example, semiconductor, magnetic, opto-magnetic, optical, or other forms of computer readable medium for storing computer readable code. Further, the invention may also cover apparatuses for practicing embodiments of the invention. Such apparatus may include circuits, dedicated and/or programmable, to carry out operations pertaining to embodiments of the invention. Examples of such apparatus include a general purpose computer and/or a dedicated computing device when appropriately programmed and may include a combination of a computer/computing device and dedicated/programmable hardware circuits (such as electrical, mechanical, and/or optical circuits) adapted for the various operations pertaining to embodiments of the invention.

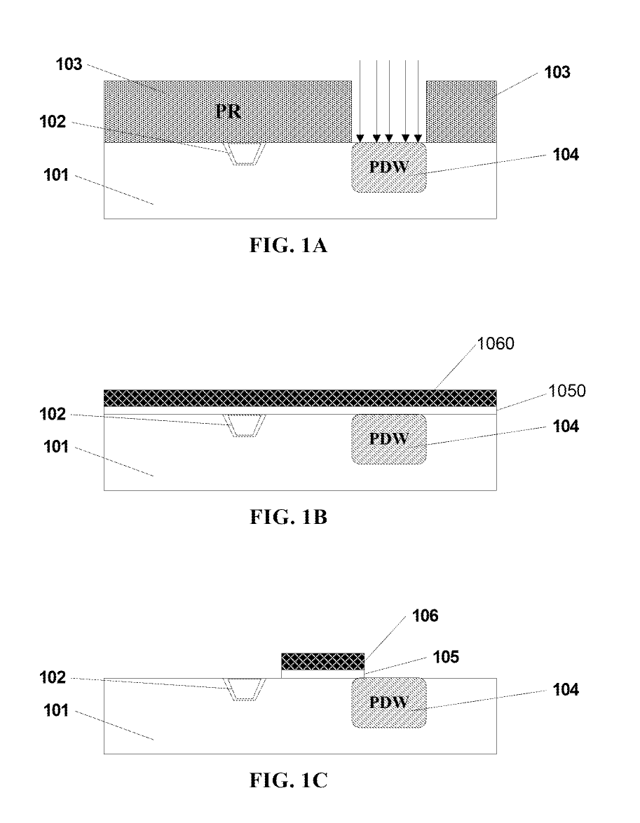

FIG. 1A, FIG. 1B, and FIG. 1C show schematic diagrams (e.g., schematic cross-sectional views) that illustrate elements and/or structures formed in a method for manufacturing a semiconductor device, such as a photodiode, in accordance with one or more embodiments of the present invention.

As illustrated in FIG. 1A, the method may include the following steps: preparing a semiconductor substrate 101 that includes a shallow trench isolation region 102; providing a photoresist 103 on the semiconductor substrate 101, wherein the photoresist 103 has an opening; and performing high-energy ion implantation on the semiconductor substrate 101 through the opening. As a result, a photodiode well 104 (or PDW 104) may be formed in the semiconductor substrate 101.

As illustrated in FIG. 1A and FIG. 1B, the method may further include the following steps: removing the photoresist 103; forming a oxide layer 1050 on the semiconductor substrate 101; and forming a polycrystalline silicon layer 1060 on the oxide layer 1050 through deposition. Each of the formation of the oxide layer 1050 and the formation of the polycrystalline silicon layer 1060 may require a high-temperature process. The high temperatures may affect doping characteristics of the PDW 104. As a result, the sensitivity of the manufactured semiconductor device may be negatively affected.

As illustrated in FIG. 1C, the method may further include the following step: performing one or more lithography processes on the polycrystalline silicon layer 1060 and the oxide layer 1050 to form a polycrystalline silicon gate electrode 106 and a gate insulating layer 105. Ideally, an edge of the polycrystalline silicon gate electrode 106 should be substantially aligned with an edge of the PDW 104 in a direction perpendicular to the semiconductor substrate 101 with minimum overlap between the polycrystalline silicon gate electrode 106 and the PDW 104 in the direction perpendicular to the semiconductor substrate 101. Nevertheless, given process precision limitations, the polycrystalline silicon gate electrode 106 may substantially overlap the PDW 104 in the direction perpendicular to the semiconductor substrate 101. The substantial overlap may cause dark current and leakage current.

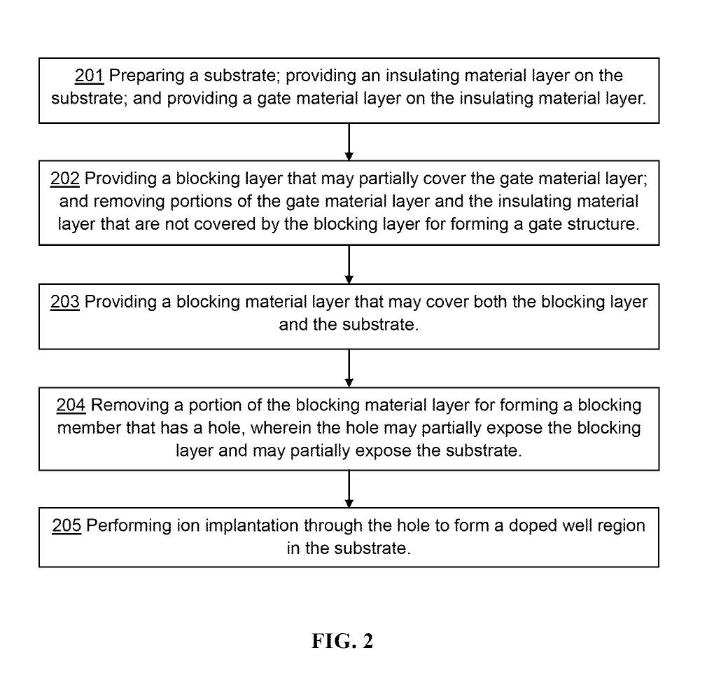

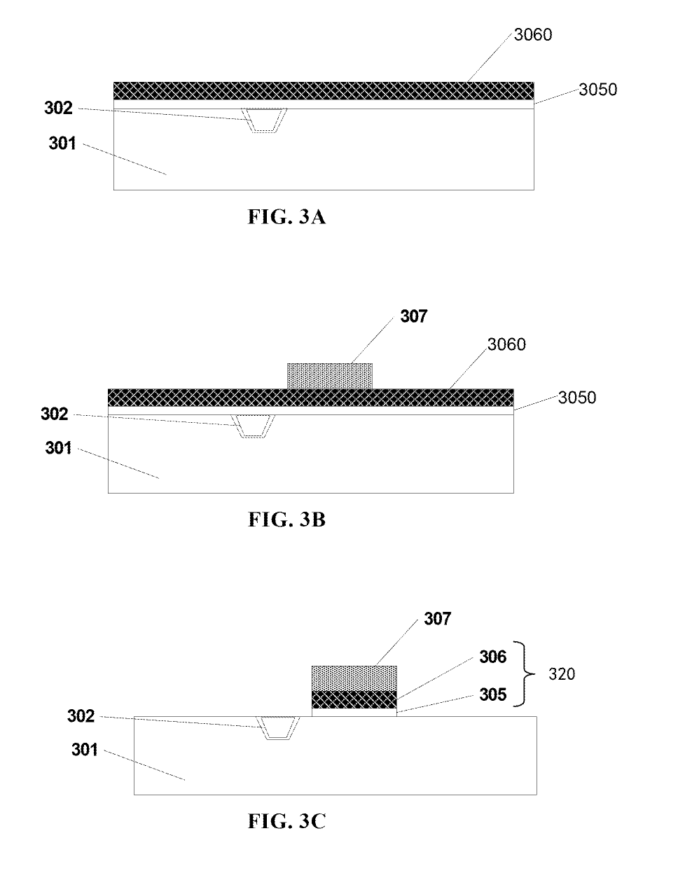

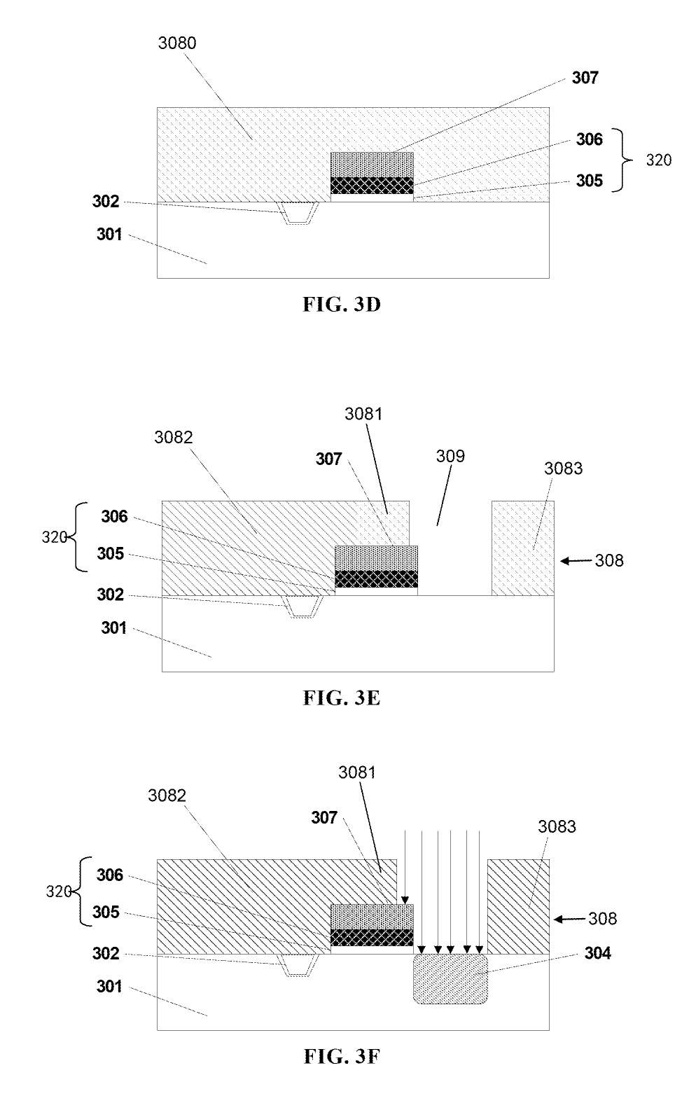

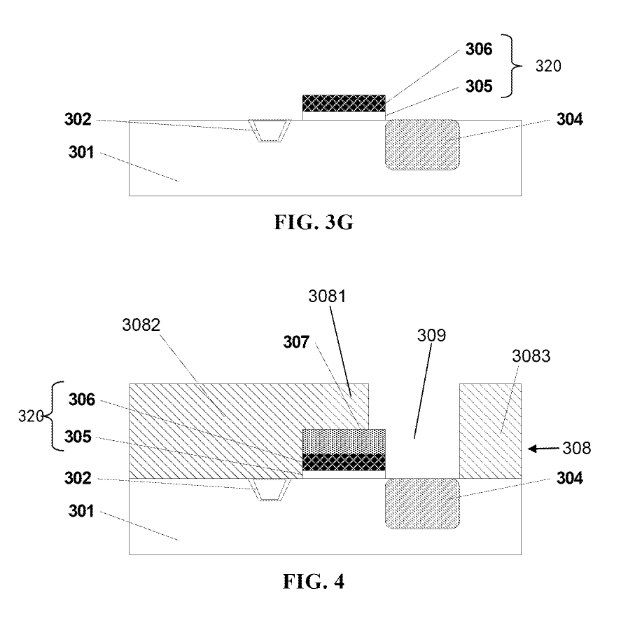

FIG. 2 shows a flowchart that illustrates steps in a method for manufacturing a semiconductor device in accordance with one or more embodiments of the present invention. FIG. 3A, FIG. 3B, FIG. 3C, FIG. 3D, FIG. 3E, FIG. 3F, and FIG. 3G show schematic diagrams (e.g., schematic cross-sectional views) that illustrate elements and/or structures formed in the method for manufacturing the semiconductor device in accordance with one or more embodiments of the present invention.

Referring to FIG. 2, the method may include steps 201, 202, 203, 204, and 205.

Referring to FIG. 2 and FIG. 3A, the step 201 may include the following sub-steps: Preparing a substrate 301; providing an insulating material layer 3050 on the substrate 301; and providing a gate material layer 3060 (e.g., a polycrystalline silicon layer) on the insulating material layer 3050. The gate material layer 3060 may overlap the substrate 301 with the insulating material layer 3050 being positioned between the gate material layer 3060 and the substrate 301.

The substrate 301 may be a semiconductor substrate, such as a silicon substrate.

The insulating material layer 3050 may be formed on the substrate 301 through deposition. Alternatively or additionally, the insulating material layer 3050 may be formed through oxidizing and/or nitrifying a portion (e.g., the top surface) of the substrate 301. The insulating material layer 3050 may be an oxide layer, such as a silicon oxide layer.

The method may include forming a dielectric region 302 (e.g., a shallow trench isolation region) in the substrate 301 before the insulating material layer 3050 and the gate material layer 3060 are provided on the substrate 301.

Referring to FIG. 2, FIG. 3A, FIG. 3B, and FIG. 3C, subsequent to the step 201, the step 202 may include the following sub-steps: providing a blocking layer 307 that may partially cover the gate material layer 3060; and removing (e.g., through one or more etching processes) portions of the gate material layer 3060 and the insulating material layer 3050 that is not covered by the blocking layer 307 for forming a gate electrode 306 and an insulating layer 305. The gate electrode 306 and the insulating layer 305 may form a gate structure 320.

The blocking layer 307 may be formed through forming a first blocking material layer on the gate material layer 3060 and then patterning the first blocking material layer. The blocking layer 307 may be formed of a first material, such as a first photoresist material or a first sacrificial material. The gate structure 320 may be formed through a lithography process using the blocking layer 307 as a mask.

A thickness of the blocking layer 307 in a direction perpendicular to (e.g., a bottom side of) the substrate 301 may be sufficiently large for protecting the gate structure 320 in subsequent process steps. The thickness of the blocking layer 307 may be configured according to, for example, an energy level associated with a subsequent ion implantation process. A higher energy level associated with the ion implantation process may require a larger thickness of the blocking layer 307. The thickness of the blocking layer 307 may be greater than or equal to 500 angstroms, for example, in a range of 2000 angstroms to 3000 angstroms.

Referring to FIG. 2, FIG. 3C, and FIG. 3D, subsequent to the step 202, the step 203 may include providing a blocking material layer 3080 that may cover both the blocking layer 307 and the substrate 301.

The blocking material layer 3080 may be formed of a second material, such as a second photoresist material or a second sacrificial material, which may be different from the first material. An etch rate of the second material may be greater than an etch rate of the first material in a first etchant and/or in light of a first wavelength. An etch rate of the first material may be greater than an etch rate of the second material in a second etchant and/or in light of a second wavelength.

In an embodiment, the first material may be an I-line photoresist material, and the second material may be a deep ultraviolet (DUV) photoresist material. In an embodiment, the first material may be more sensitive to light of a 365-nm wavelength than the second material, and the second material may be more sensitive to light of a 243-nm wavelength.

Referring to FIG. 2, FIG. 3D, and FIG. 3E, subsequent to the step 203, the step 204 may include removing (e.g., through one or more lithography processes and/or one or more etching processes) a portion of the blocking material layer 3080 for forming a blocking member 308 that has an hole 309, wherein the hole 309 may partially expose the blocking layer 307 and may partially expose the substrate 301. Being a remaining portion of the blocking material layer 3080, the blocking member 308 may be formed of the aforementioned second material.

Because of photosensitivity difference and/or etch selectivity, the blocking layer 307 may not be significantly affected when in the process of removing the portion of the blocking material layer 3080. An exposed portion of the blocking layer 307 and the underlying portion of the gate structure 320 may extend into the hole 309 and may be at least partially exposed by the hole 309.

An opening of the hole 309 may be larger than the opening of the photoresist 103 illustrated in FIG. 1A. Advantageously, embodiments of the invention may require less process precision and may provide higher fault tolerance than conventional techniques.

As a result of the step 204, the blocking layer 307 may be positioned between the gate electrode 306 and a portion 3081 of the blocking member 308 in a direction perpendicular to (e.g., a bottom side of) the substrate 301. A portion 3082 of the blocking member 308 may overlap the dielectric region 302 in the direction perpendicular to the substrate 301 before the ion implantation. The portion 3081 of the blocking member 308 may be positioned between the portion 3082 of the blocking member 308 and the hole 309 in a direction parallel to the substrate 301. The hole 309, the gate electrode 306, the blocking layer 307, and the portion 3081 of the blocking member 308 may be positioned between the portion 3082 of the blocking member 308 and a portion 3083 of the blocking member 308 in the direction parallel to the substrate 301.

The portion 3081 of the blocking member 308 may be spaced from the portion 3083 of the blocking member 308 in the direction parallel to the substrate 301. Each of the blocking layer 307, the gate electrode 306, and the insulating layer 305 may be spaced from the portion 3083 of the blocking member 308 in the direction parallel to the substrate 301. A distance between the blocking layer 307 and the portion 3083 of the blocking member 308 (in the direction parallel to the substrate 301) may be less than a distance between the portion 3081 of the blocking member 308 and the portion 3083 of the blocking member 308 (in the direction parallel to the substrate 301). A distance between the gate electrode 306 and the portion 3083 of the blocking member 308 (in the direction parallel to the substrate 301) may be less than a distance between the portion 3081 of the blocking member 308 and the portion 3083 of the blocking member 308 (in the direction parallel to the substrate 301). A distance between the insulating layer 305 and the portion 3083 of the blocking member 308 (in the direction parallel to the substrate 301) may be less than a distance between the portion 3081 of the blocking member 308 and the portion 3083 of the blocking member 308 (in the direction parallel to the substrate 301).

Referring to FIG. 2, FIG. 3E, and FIG. 3F, subsequent to the step 204, the step 205 may include performing ion implantation through the hole 309 to form a doped well region 304 (e.g., a photodiode well region) in the substrate 301.

The blocking member 308 and the exposed portion of the blocking layer 307 may function as masks in the ion implantation process. The exposed portion of the blocking layer 307 may substantially protect the underlying portion of the gate structure 320 from damage and may substantially block the underlying portion of the substrate 301 from ion implantation.

During the ion implantation, some ions may be blocked by the exposed portion of the blocking layer 307 (which is exposed by the hole 309), and some ions may be provided through a portion of the hole 309 that is positioned between the gate electrode 306 and the portion 3083 of the blocking member 308 into the exposed portion of the substrate 301 to form the doped well region 304. Since an exposed edge of the gate electrode 306 may be substantially aligned with an exposed edge of the blocking layer 307, an edge of the doped well region 304 may be substantially aligned with the exposed edge of the gate electrode 306 in the direction perpendicular to the substrate 301. As a result, less than 5%, e.g., substantially 0%, of the doped well region 304 may overlap the gate electrode 306 in the direction perpendicular to the substrate 301. Advantageously, dark current in the semiconductor device may be minimized, and sensitivity and/or efficiency of the semiconductor device may be optimized.

According to embodiments of the invention, the doped well region 304 may be formed after the gate structure 320 has been formed. Therefore, high-temperature processes required for the formation of the gate structure 320 may not significantly affect the subsequently formed doped well region 304. Advantageously, satisfactory quality of the doped well region 304 may be regained in the manufacturing process for the semiconductor device.

The structure discussed with reference to FIG. 3F may represent a semiconductor device in accordance with one or more embodiments of the present invention. The semiconductor device may be used for manufacturing a further-processed semiconductor device, such as an image sensor device.

Referring to FIG. 3F and FIG. 3G, subsequent to the step 205, the method may include removing the blocking member 308 and the blocking layer 307 after the doped well region 304 has been formed. The blocking member 308 and the blocking layer 307 may be sequentially or substantially simultaneously removed through one or more lithography processes and/or one or more etching processes. The blocking member 308 and the blocking layer 307 may be substantially simultaneously removed through one or more ashing processes.

The structure illustrated in FIG. 3G may represent a semiconductor device in accordance with one or more embodiments of the present invention. As an example, the semiconductor device may be an image sensor device. The semiconductor device may include the following elements: the substrate 301 (e.g., a semiconductor substrate) that may include a doped well region 304; and the gate structure 320 that may include the gate electrode 306 and the insulating layer 305 and may overlap the substrate 301. In the semiconductor device, an edge of the doped well region 304 may be substantially aligned with an edge of the gate electrode 306 in a direction perpendicular to the substrate 301, and less than 5%, e.g., substantially 0%, of the doped well region 304 may overlap the gate electrode 306 in the direction perpendicular to the substrate 301. Advantageously, dark current in the semiconductor device may be minimized, and sensitivity and/or efficiency of the semiconductor device may be optimized.

FIG. 4 shows a schematic diagram (e.g., a schematic cross-sectional view) that illustrates elements of a semiconductor device in accordance with one or more embodiments of the present invention. The semiconductor device may include one or more of the elements, structures, features, and advantages discussed with reference to FIGS. 3A to 3G. For example, the semiconductor device may include the following elements: a substrate 301 (e.g., a semiconductor substrate) that may include a doped well region 304 (e.g., a photodiode well region); a blocking member 308 that may overlap the substrate 301 and may have an hole 309, wherein the hole 309 may expose the doped well region 304; a blocking layer 307 that may be positioned between the substrate 301 and a portion 3081 of the blocking member 308 in a direction perpendicular to (e.g., a bottom side of) the substrate 301 and may be partially exposed by the hole 309; and a gate electrode 306 that may be positioned between the substrate 301 and the blocking layer 307. The semiconductor device may be used for manufacturing a further-processed semiconductor device, such as a semiconductor device discussed with reference to FIG. 3G.

The semiconductor device may include an insulating layer 305 positioned between the substrate 301 and the gate electrode 306. The gate electrode 306 and the insulating layer 305 may form a gate structure 320.

The blocking layer 307 may be formed of a first material. The blocking member 308 may be formed of a second material different from the first material. An etch rate of the second material may be greater than an etch rate of the first material in a first etchant and/or in light of a first wavelength.

A thickness of the blocking layer 307 in the direction perpendicular to the substrate 301 may be greater than or equal to 500 angstroms, e.g., in a range of 2000 angstroms to 3000 angstroms.

An edge of the gate electrode 306 may be substantially aligned with an edge of the doped well region 304 in the direction perpendicular to the substrate 301.

The substrate 301 may include a dielectric region 302, e.g., a shallow trench isolation region. A portion 3082 of the blocking member 308 may overlap the dielectric region 302 in the direction perpendicular to the substrate 301. The gate electrode 306, the blocking layer 307, and the hole 309 may be positioned between the portion 3082 of the blocking member 308 and a portion 3083 of the blocking member 308 in a direction parallel to the substrate 301.

A distance between the gate electrode 306 and the portion 3083 of the blocking member 308 in the direction parallel to the substrate 301 may be less than a distance between the portion 3081 of the blocking member 308 and the portion 3083 of the blocking member 308 in the direction parallel to the substrate 301.

A distance between the blocking layer 307 and the portion 3083 of the blocking member 308 in the direction parallel to the substrate 301 may be less than a distance between the portion 3081 of the blocking member 308 and the portion 3083 of the blocking member 308 in the direction parallel to the substrate 301.

According to embodiments of the invention, in a process for manufacturing a semiconductor device, a doped well region may be formed in a substrate after a gate structure has been formed. Therefore, the doped well region may not be significantly affected by high-temperature processes performed for forming the gate structure. Advantageously, satisfactory quality of the doped well region may be retained, and the semiconductor device may have satisfactory quality.

According to embodiments of the invention, in a process for manufacturing a semiconductor device, an edge of a blocking layer may be substantially aligned with an edge of a gate structure, and the blocking layer may function as a mask during an ion implantation process performed for forming a doped well region in a substrate. Accordingly, an edge of the doped well region may be substantially aligned with the edge of the gate structure, and the doped well region may not significantly overlap the gate structure. Therefore, dark current in a semiconductor device may be minimized. Advantageously, satisfactory sensitivity and/or satisfactory efficiency of the semiconductor device may be attained.

While this invention has been described in terms of several embodiments, there are alterations, permutations, and equivalents, which fall within the scope of this invention. It should also be noted that there are many alternative ways of implementing the methods and apparatuses of the present invention. Furthermore, embodiments of the present invention may find utility in other applications. The abstract section is provided herein for convenience and, due to word count limitation, is accordingly written for reading convenience and should not be employed to limit the scope of the claims. It is therefore intended that the following appended claims be interpreted as including all such alterations, permutations, and equivalents as fall within the true spirit and scope of the present invention.

What is claimed is:

1. A method for manufacturing a semiconductor device, the method comprising:
preparing a substrate;
providing a gate material layer that overlaps the substrate;
providing a blocking layer that partially covers the gate material layer;
removing a portion of the gate material layer that is not covered by the blocking layer for forming a gate electrode;
providing a blocking material layer that covers both the blocking layer and the substrate;
removing a portion of the blocking material layer for forming a blocking member that has a hole, wherein the hole partially exposes the blocking layer and partially exposes the substrate; and
performing ion implantation through the hole to form a doped well region in the substrate.

2. The method of claim 1,
wherein the blocking layer is formed of a first material,
wherein the blocking material layer is formed of a second material different from the first material, and
wherein an etch rate of the second material is greater than an etch rate of the first material in at least one of a first etchant and light of a first wavelength.

3. The method of claim 1, wherein during the ion implantation some ions are provided through a portion of the hole that is positioned between the gate electrode and a portion of the blocking member.

4. The method of claim 1, wherein during the ion implantation some ions are blocked by an exposed portion of the blocking layer that is exposed by the hole.

5. The method of claim 1, further comprising: removing the blocking member and the blocking layer after the doped well region has been formed.

6. The method of claim 1, wherein a thickness of the blocking layer in a direction perpendicular to the substrate is greater than or equal to 500 angstroms.

7. The method of claim 1, wherein an edge of the doped well region is substantially aligned with an edge of the gate electrode in a direction perpendicular to the substrate.

8. The method of claim 1, further comprising: forming a dielectric region in the substrate,
wherein the blocking layer is positioned between the gate electrode and a first portion of the blocking member in a direction perpendicular to the substrate before the ion implantation,
wherein a second portion of the blocking member overlaps the dielectric region in the direction perpendicular to the substrate before the ion implantation, and
wherein the first portion of the blocking member is positioned between the second portion of the blocking member and the hole in a direction parallel to the substrate before the ion implantation.

9. The method of claim 8, wherein the hole, the gate electrode, the blocking layer, and the first portion of the blocking member are positioned between the second portion of the blocking member and a third portion of the blocking member in the direction parallel to the substrate before the ion implantation.

10. The method of claim 1,
wherein the blocking layer is positioned between the gate electrode and a first portion of the blocking member in a direction perpendicular to the substrate before the ion implantation,
wherein the first portion of the blocking member is spaced from a second portion of the blocking member in a direction parallel to the substrate before the ion implantation,
wherein the gate electrode is spaced from the second portion of the blocking member in the direction parallel to the substrate before the ion implantation, and
wherein a distance between the gate electrode and the second portion of the blocking member is less than a distance between the first portion of the blocking member and the second portion of the blocking member before the ion implantation.

11. A semiconductor device comprising:
a substrate that includes a doped well region; and
a gate electrode that overlaps the substrate,
wherein an edge of the gate electrode is substantially aligned with an edge of the doped well region in a direction perpendicular to a side of the substrate.

12. The semiconductor device of claim 11, wherein less than 5% of the doped well region overlaps the gate electrode in the direction perpendicular to the side of the substrate.

13. The semiconductor device of claim 11, further comprising:
a blocking layer that is positioned on the gate electrode; and
a blocking member that partially covers the blocking layer and has a hole, wherein the hole partially exposes the blocking layer and exposes the doped well region.

14. A semiconductor device comprising:
a substrate that includes a doped well region;
a blocking member that overlaps the substrate and has a hole, wherein the hole exposes the doped well region;
a blocking layer positioned between the substrate and a first portion of the blocking member in a direction perpendicular to the substrate and partially exposed by the hole; and
a gate electrode positioned between the substrate and the blocking layer.

15. The semiconductor device of claim 14,
wherein the blocking layer is formed of a first material,
wherein the blocking member is formed of a second material different from the first material, and
wherein an etch rate of the second material is greater than an etch rate of the first material in at least one of a first etchant and light of a first wavelength.

16. The semiconductor device of claim 14, wherein a thickness of the blocking layer in the direction perpendicular to the substrate is greater than or equal to 500 angstroms.

17. The semiconductor device of claim 14, wherein an edge of the gate electrode is substantially aligned with an edge of the doped well region in the direction perpendicular to the substrate.

18. The semiconductor device of claim 14,
wherein the substrate further includes a dielectric region,
wherein a second portion of the blocking member overlaps the dielectric region in the direction perpendicular to the substrate, and
wherein the gate electrode, the blocking layer, and the hole are positioned between the second portion of the blocking member and a third portion of the blocking member in a direction parallel to the substrate.

19. The semiconductor device of claim 18, wherein a distance between the gate electrode and the third portion of the blocking member in the direction parallel to the substrate is less than a distance between the first portion of the blocking member and the third portion of the blocking member in the direction parallel to the substrate.

20. The semiconductor device of claim 18, wherein a distance between the blocking layer and the third portion of the blocking member in the direction parallel to the substrate is less than a distance between the first portion of the blocking member and the third portion of the blocking member in the direction parallel to the substrate.
